(19) United States
(12) Patent Application Publication
(10) Pub. No.: US 2026/0164650 A1
(43) Pub. Date: Jun. 11, 2026

(54) SUB WORDLINE DRIVER AND SEMICONDUCTOR MEMORY DEVICE INCLUDING SAME

(71) Applicant: Samsung Electronics Co., Ltd., Suwon-si (KR)

(72) Inventors: Kyuseok LEE, Suwon-si (KR); Jeonghoon OH, Suwon-si (KR); Joonyoung KOH, Suwon-si (KR); Hyunju SUNG, Suwon-si (KR); Sungho JANG, Suwon-si (KR); Haein JUNG, Suwon-si (KR); Seungho HONG, Suwon-si (KR)

(21) Appl. No.: 19/277,614

(22) Filed: Jul. 23, 2025

(30) Foreign Application Priority Data
Dec. 11, 2024 (KR) 10-2024-0183620

(51) Int. Cl. H10B 12/00; G11C 11/408

(52) U.S. Cl. CPC H10B 12/50; G11C 11/4085; H10B 12/315

(57) ABSTRACT

A sub wordline driver may include a substrate including an active pattern, wherein the active pattern includes a first channel region, a second channel region, and a third channel region, which are disposed to be sequentially spaced apart in a first horizontal direction, a first gate electrode disposed on the first channel region and extending in a second horizontal direction perpendicular to the first horizontal direction, a second gate electrode disposed on the second channel region, and a third gate electrode disposed on the third channel region and extending in the second horizontal direction, wherein the second channel region extends in a third horizontal direction that forms an acute angle with the first horizontal direction, and a width of the second channel region in the third horizontal direction is greater than a width of the second channel region in the first horizontal direction.

### CROSS-REFERENCE TO RELATED APPLICATION(S)

This application claims priority under 35 U.S.C. § 119 to Korean Patent Application No. 10-2024-0183620, filed on Dec. 11, 2024, in the Korean Intellectual Property Office, the entire contents of which are hereby incorporated by reference.

### BACKGROUND

### Field of the Inventions

The present disclosure relates to a sub wordline driver and a semiconductor memory device including the same.

### Description of Related Art

According to the high performance needs of users, the capacity and speed of semiconductor memory devices used in various electronic systems are increasing dramatically. In particular, dynamic random access memory (DRAM) is considered a representative example of a volatile memory device. The memory cell of the DRAM stores data in the form of charges stored in the cell capacitor. The DRAM writes or reads data to or from the memory cells using wordlines and bit lines. The memory cells connected to the wordlines form a row and operate according to the voltage applied to the wordline.

As the integration density of the DRAM increases and the capacity increases, the number of memory cells connected to a single wordline increases, and the spacing between the wordlines is shrinking. The progressive miniaturization of the memory cells requires further miniaturization of the core/periphery components for the operation of the memory cells. For example, as the pitch of the memory cells decreases, miniaturization of the sub wordline drivers, the bit line sense amplifiers, etc. is required.

### SUMMARY

In order to solve one or more problems (e.g., the problems described above and/or other problems not explicitly described herein), the present disclosure provides a sub wordline driver with improved electrical characteristics and integration density.

In order to solve one or more problems (e.g., the problems described above and/or other problems not explicitly described herein), the present disclosure provides a semiconductor memory device with improved electrical characteristics and integration density.

According to some embodiments of the present disclosure, by obliquely arranging the channel region of the keeping transistor, the length of the channel of the keeping transistor may increase. Accordingly, the electrical characteristics of the sub wordline drivers and the semiconductor memory device can be improved.

According to some embodiments, by obliquely arranging the channel of the keeping transistor, the sub wordline drivers can include the keeping transistor having a longer channel relative to the same area. Accordingly, the area in which the keeping transistor is disposed can be reduced, and the integration density of the sub wordline drivers and the semiconductor memory device can be improved.

According to some embodiments of the present disclosure, a sub wordline driver may include a substrate including an active pattern, wherein the active pattern includes a first channel region, a second channel region, and a third channel region, which are disposed to be sequentially spaced apart in a first horizontal direction, a first gate electrode disposed on the first channel region and extending in a second horizontal direction perpendicular to the first horizontal direction, a second gate electrode disposed on the second channel region, and a third gate electrode disposed on the third channel region and extending in the second horizontal direction, wherein the second channel region extends in a third horizontal direction that forms an acute angle with the first horizontal direction, and a width of the second channel region in the third horizontal direction is greater than a width of the second channel region in the first horizontal direction.

According to some embodiments of the present disclosure, a semiconductor memory device may include a substrate including an active pattern, and a first gate electrode, a second gate electrode, and a third gate electrode, which are arranged on the active pattern and spaced apart from each other in a first horizontal direction, wherein the active pattern includes a first portion overlapping with the first gate electrode in a vertical direction, a second portion overlapping with the second gate electrode in the vertical direction, and a third portion overlapping with the third gate electrode in the vertical direction, and the active pattern includes a first recess and a second recess, which are disposed between the first portion and the third portion and spaced apart from each other with the second portion interposed therebetween.

According to some embodiments of the present disclosure, a sub wordline driver may include a memory cell including a bit line, a wordline intersecting with the bit line, and an information storage structure, and a sub wordline driver configured to control the wordline, wherein the sub wordline driver includes, a substrate including an active pattern, wherein the active pattern includes a first channel region, a second channel region, and a third channel region, which are disposed to be spaced apart from each other in a first horizontal direction, a device isolation film disposed in the substrate and defining the active pattern, a first gate electrode disposed on the first channel region and extending in a second horizontal direction perpendicular to the first horizontal direction, a second gate electrode disposed on the second channel region, and a third gate electrode disposed on the third channel region and extending in the second horizontal direction, the second channel region extends in a third horizontal direction that forms an acute angle with the first horizontal direction, and a width of the second channel region in the third horizontal direction is greater than a width of the second channel region in the first horizontal direction, and the active pattern includes a pair of recesses disposed in an alternating fashion between the first channel region and the third channel region, and spaced apart from each other with the second channel region interposed therebetween.

### BRIEF DESCRIPTION OF THE DRAWINGS

The above and other embodiments and features of the present disclosure will become more apparent by describing in detail example embodiments thereof with reference to the attached drawings, in which:

FIG. 1 is a schematic plan view provided to explain a semiconductor memory device according to some example embodiments;

FIG. 2 is a block diagram provided to explain the sub wordline drivers according to some example embodiments;

FIG. 3 is an example circuit diagram provided to explain the structures of the first sub wordline driver and the second sub wordline driver of FIG. 2;

FIG. 4 is a plan view provided to explain an active pattern of the sub wordline driver according to some example embodiments;

FIG. 5 is a plan view provided to explain the sub wordline driver according to some example embodiments;

FIG. 6 is an enlarged view provided to explain a region Q1 of FIG. 5;

FIG. 7 is a cross-sectional view taken along line A-A of FIG. 6;

FIG. 8 is a cross-sectional view taken along the line B-B of FIG. 6;

FIG. 9 is a diagram provided to explain a sub wordline driver according to some example embodiments;

FIG. 10 is a diagram provided to explain the sub wordline driver according to some example embodiments;

FIG. 11 is a diagram provided to explain the sub wordline driver according to some example embodiments;

FIG. 12 is a diagram provided to explain a sub wordline driver according to some example embodiments;

FIG. 13 is a diagram provided to explain the sub wordline driver according to some example embodiments;

FIG. 14 is a diagram provided to explain a sub wordline driver according to some example embodiments;

FIG. 15 is a plan view provided to explain a memory cell of a semiconductor device according to some example embodiments;

FIG. 16 is a plan view provided to explain a memory cell of a semiconductor device according to some example embodiments;

FIG. 17 is a cross-sectional view taken along line C-C of FIG. 15;

FIG. 18 is a cross-sectional view taken along line D-D of FIG. 15.

### DETAILED DESCRIPTION

In the present disclosure, terms such as first, second, etc. may be used to describe various devices or components, but the devices or components are not limited by these terms. It should be understood that these terms are only used to distinguish one element or component from another element or component. It goes without saying that the first element or component mentioned below may be the second element or component within the technical idea of the present disclosure. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

Although the figures described herein may be referred to using language such as “one embodiment,” or “certain embodiments,” these figures, and their corresponding descriptions are not intended to be mutually exclusive from other figures or descriptions, unless the context so indicates. Therefore, certain aspects from certain figures may be the same as certain features in other figures, and/or certain figures may be different representations or different portions of a particular exemplary embodiment.

A semiconductor device and a method for manufacturing the same according to example embodiments will be described in detail with reference to the drawings.

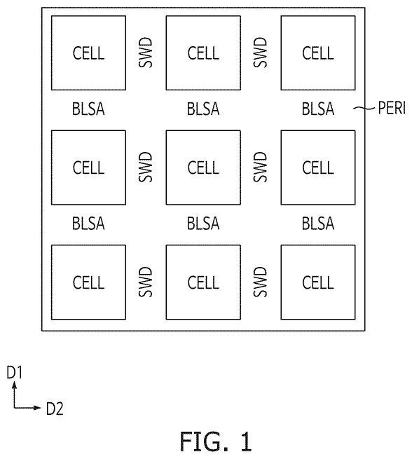

FIG. 1 is a schematic plan view provided to explain a semiconductor memory device according to some example embodiments.

Referring to FIG. 1, the semiconductor memory device may include cell regions CELL and core/periphery regions PERI.

The cell regions CELL and the core/periphery regions PERI may be disposed on a substrate. Memory cells for storing data in the cell regions CELL may be arranged in an array form. For example, the cell regions CELL may include DRAM cells. The core/periphery regions PERI may be disposed around the cell regions CELL or disposed in separate regions different from the cell regions CELL. Control devices and dummy devices may be formed on the core/periphery regions PERI. Circuits necessary for controlling the memory cells in the cell regions CELL may be provided on the core/periphery regions PERI.

A plurality of sub wordline drivers SWD and a plurality of bit line sense amplifiers BLSA may be disposed on the core/periphery regions PERI. For example, the cell regions CELL and the sub wordline drivers SWD may be alternately arranged in one direction (e.g., in a second direction D2), and the cell regions CELL and the bit line sense amplifiers BLSA may be alternately arranged in a direction (e.g., a first direction D1) perpendicular to the one direction. However, the arrangement of the cell regions CELL and the core/periphery regions PERI is an example, and embodiments are not limited thereto.

The sub wordline drivers SWD may control and operate the wordlines of the cell regions CELL. For example, the sub wordline driver SWD may enable a wordline connected to a gate of a memory cell transistor. The bit line sense amplifier BLSA may operate a bit line of the cell region CELL. The bit line sense amplifier BLSA may enable a bit line of the memory cell transistor.

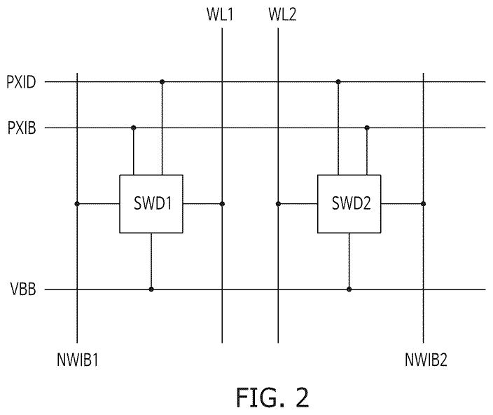

FIG. 2 is a block diagram provided to explain the sub wordline drivers according to some example embodiments.

Referring to FIG. 2, a first sub wordline driver SWD1 and a second sub wordline driver SWD2 for driving a first wordline WL1 and a second wordline WL2, respectively, may be provided. Each of the first sub wordline driver SWD1 and the second sub wordline driver SWD2 may receive a first driving signal PXID and a second driving signal PXIB.

The first sub wordline driver SWD1 may be activated in response to a first wordline enable signal NWIB1. If the first wordline enable signal NWIB1 is provided at a low level, the first sub wordline driver SWD1 may provide the wordline WL1 with a high voltage provided through the first driving signal PXID. If the first wordline enable signal NWIB1 is provided at a high level, the first sub wordline driver SWD1 may block the first driving signal PXID and precharge the first wordline WL1 with a negative voltage VBB.

The second sub wordline driver SWD2 may be activated in response to a second wordline enable signal NWIB2. If the second wordline enable signal NWIB2 is provided at a low level, the second sub wordline driver SWD2 may provide the second wordline WL2 with a high voltage provided through the first driving signal PXID. If the second wordline enable signal NWIB2 is provided at a high level, the second sub wordline driver SWD2 may block the first driving signal PXID and precharge the second wordline WL2 with the negative voltage VBB.

Each of the first sub wordline driver SWD1 and the second sub wordline driver SWD2 may include a keeping transistor. A keeping transistor may be a transistor that is used to maintain a state or value. For example, a keeping transistor may maintain a stored value in a memory device. In some embodiments, the first sub wordline driver SWD1 and the second sub wordline driver SWD2 may share one keeping transistor. The keeping transistor may maintain the wordlines WL1 and WL2 at the negative voltage VBB after the precharge operation of the sub wordline drivers SWD1 and SWD2. The keeping transistor may fix the wordlines WL1 and WL2 at the negative voltage VBB level in response to the second driving signal PXIB. Accordingly, despite fluctuations in the levels of the wordline enable signals NWIB1 and NWIB2 or noise, the keeping transistor may maintain the wordlines WL1 and WL2 at a stable voltage value.

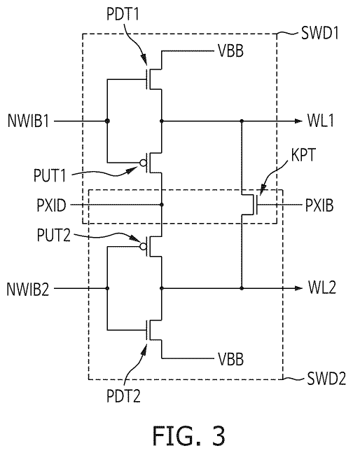

FIG. 3 is an example circuit diagram provided to explain the structures of the first sub wordline driver and the second sub wordline driver of FIG. 2.

Referring to FIG. 3, the first sub wordline driver SWD1 according to some embodiments may include a first pull-down transistor PDT1, a first pull-up transistor PUT1, and a keeping transistor KPT, and the second sub wordline driver SWD2 may include a second pull-down transistor PDT2, a second pull-up transistor PUT2, and the keeping transistor KPT.

The first driving signal PXID and the second driving signal PXIB may be provided from the driving voltage generator to the first sub wordline driver SWD1. For example, the first driving signal PXID may be provided to the first pull-up transistor PUT1, and the second driving signal PXIB may be provided to the keeping transistor KPT. The first wordline enable signal NWIB1 may be provided from the row decoder to the first sub wordline driver SWD1. For example, the first wordline enable signal NWIB1 may be provided to each of the first pull-down transistor PDT1 and the first pull-up transistor PUT1. The first pull-up transistor PUT1 may be a PMOSFET, and the first pull-down transistor PDT1 and the keeping transistor KPT may be NMOSFETs.

In response to the first wordline enable signal NWIB1, the first pull-up transistor PUT1 may pull up the first wordline WL1 to the level of the first driving signal PXID. In response to the first wordline enable signal NWIB1, the first pull-down transistor PDT1 may pull down the first wordline WL1 to the negative voltage VBB. The keeping transistor KPT1 may maintain the first wordline WL1 at the level of the negative voltage VBB when the first wordline WL1 is deactivated. To this end, the keeping transistor KPT may switch between a source to which the negative voltage VBB is provided and a drain connected to the first wordline WL1 in response to the second driving signal PXIB that is in a complementary relationship with the first driving signal PXID.

The first driving signal PXID and the second driving signal PXIB may be provided from the driving voltage generator to the second sub wordline driver SWD2. For example, the first driving signal PXID may be provided to the second pull-up transistor PUT2, and the second driving signal PXIB may be provided to the keeping transistor KPT. The second wordline enable signal NWIB2 may be provided from the row decoder to the second sub wordline driver SWD2. The second pull-up transistor PUT2 may be a PMOSFET, and the second pull-down transistor PDT2 may be an NMOSFET.

The second pull-up transistor PUT2 may pull up the second wordline WL2 to the level of the first driving signal PXID in response to the second wordline enable signal NWIB2. The second pull-down transistor PDT2 may pull down the second wordline WL2 to a negative voltage VBB in response to the second wordline enable signal NWIB2. The keeping transistor KPT may maintain the second wordline WL2 at the level of the negative voltage VBB when the second wordline WL2 is deactivated. To this end, the keeping transistor KPT may switch between a source to which the negative voltage VBB is provided and a drain connected to the second wordline WL2 in response to the second driving signal PXIB that is in a complementary relationship with the first driving signal PXID.

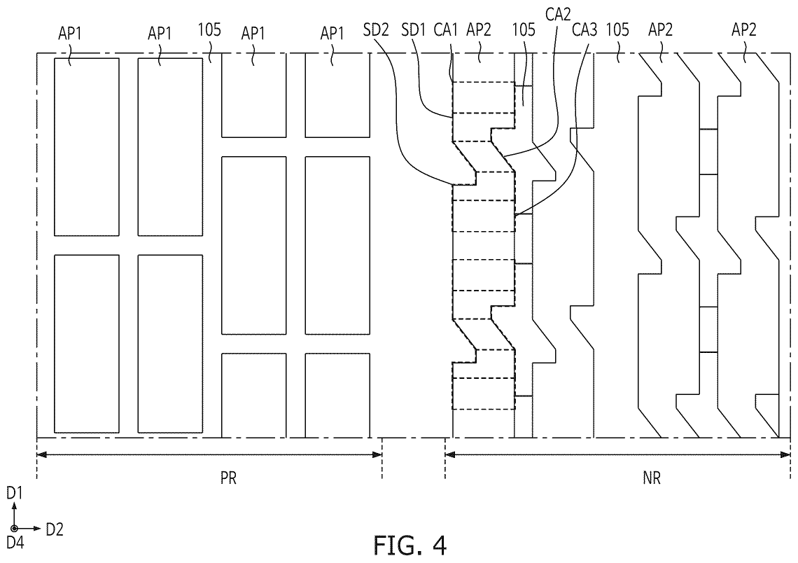

FIG. 4 is a plan view provided to explain an active pattern of the sub wordline driver according to some example embodiments.

Referring to FIG. 4, the sub wordline driver according to some embodiments may include a first active pattern AP1 and a second active pattern AP2. The first active pattern AP1 may be disposed on a PMOS region PR of the substrate, and the second active pattern AP2 may be disposed on an NMOS region NR of the substrate. The PMOS region PR may be a region where the PMOSFET is disposed, and the NMOS region NR may be a region where the NMOSFET is disposed. The first active pattern AP1 and the second active pattern AP2 may be defined by a device isolation film 105. From a planar perspective, the device isolation film 105 may surround the first active pattern AP1 and the second active pattern AP2.

The first active pattern AP1 may extend lengthwise in the first direction D1. The first active patterns AP1 may be disposed to be spaced apart from each other at regular intervals in the first direction D1. In some embodiments, the first active patterns AP1 may be arranged in pairs in the first direction D1. For example, the first active pattern AP1 arranged in the first direction D1 may be arranged in the same shape as a first active pattern AP1 that is adjacent in the second direction D2.

The first active pattern AP1 may include a source region, a drain region, and a channel region. The source region, the drain region, and the channel region of the first active pattern AP1 may form a PMOSFET. For example, the first active pattern AP1 may be a region where the first pull-up transistor PUT1 and the second pull-up transistor PUT2 of FIG. 3 are disposed.

The second active pattern AP2 may extend in the first direction D1. The second active pattern AP2 may be spaced apart from the adjacent second active pattern AP2 in the second direction D2. A plurality of second active patterns AP2 may be aligned in the second direction D2. In some embodiments, the second active patterns AP2 may be arranged in pairs. For example, the second active pattern AP2 and a second active pattern AP2 that is adjacent in the second direction D2 may be disposed to have the same shape.

The second active pattern AP2 may include a source region, a drain region, and a channel region. The source region, the drain region, and the channel region of the second active pattern AP2 may form an NMOSFET. For example, the second active pattern AP2 may be a region where the first pull-down transistor PDT1, the second pull-down transistor PDT2, and the keeping transistor KPT of FIG. 3 are disposed.

The second active pattern AP2 may include a first channel region CA1, a second channel region CA2, a third channel region CA3, a first source/drain region SD1, and a second source/drain region SD2. Hereinafter, the second active pattern AP2 will be described in detail.

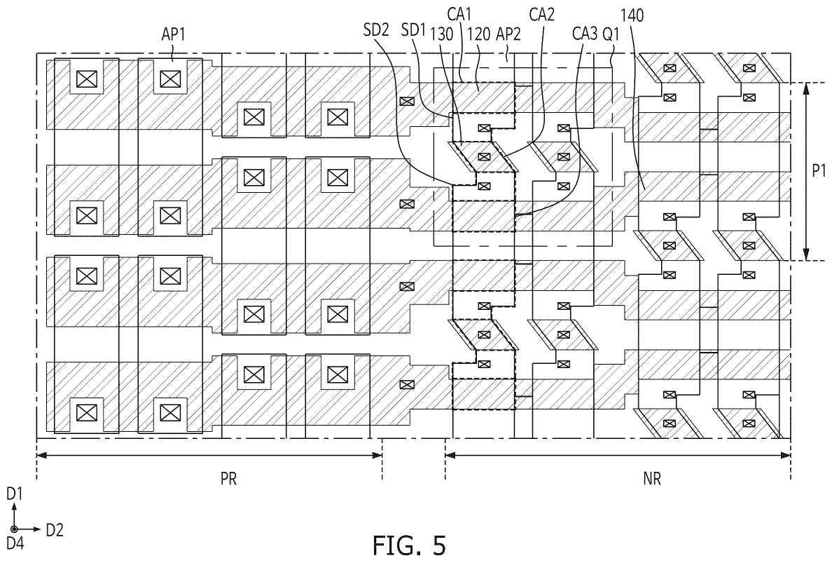

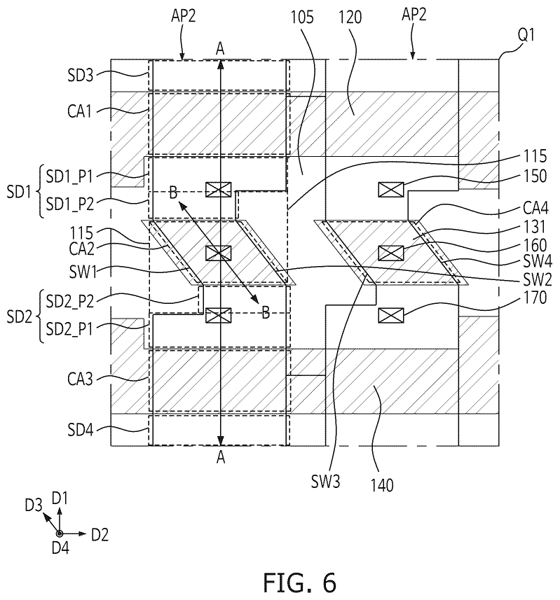

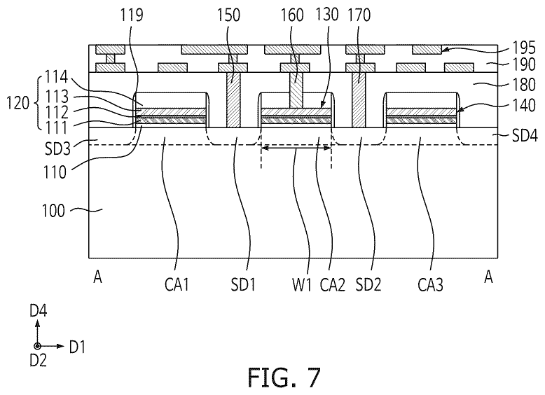

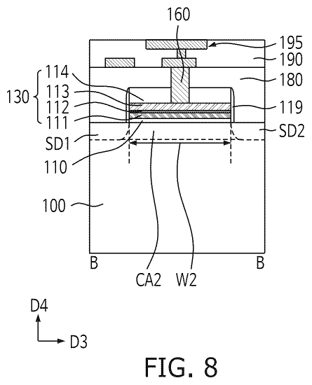

FIG. 5 is a plan view provided to explain the sub wordline driver according to some example embodiments. FIG. 6 is an enlarged view provided to explain a region Q1 of FIG. 5. FIG. 7 is a cross-sectional view taken along line A-A of FIG. 6. FIG. 8 is a cross-sectional view taken along the line B-B of FIG. 6.

Referring to FIGS. 5 to 8, as well as FIG. 3, the sub wordline drivers SWD1 and SWD2 according to some embodiments may include a substrate 100, the second active pattern AP2, a first gate electrode 120, a second gate electrode 130, a third gate electrode 140, a first source/drain contact 150, a gate contact 160, a second source/drain contact 170, etc.

The substrate 100 may be a semiconductor substrate including silicon, germanium, or silicon-germanium. The device isolation film 105 may be formed of or include silicon oxide. The device isolation film 105 may be disposed in the substrate 100.

The second active pattern AP2 may be provided on the substrate 100. The second active pattern AP2 may include a first channel region CA1, a second channel region CA2, a third channel region CA3, a first source/drain region SD1, a second source/drain region SD2, a third source/drain region SD3, and a fourth source/drain region SD4.

The first gate electrode 120 may extend in the second direction D2 and may intersect with the second active pattern AP2. The first gate electrode 120 may be disposed on the first channel region CA1. The first channel region CA1 may be defined as a region of the second active pattern AP2 that overlaps with the first gate electrode 120 in a fourth direction D4.

In some embodiments, the third source/drain region SD3, the first channel region CA1, and the first source/drain region SD1 may form the first pull-down transistor PDT1 of FIG. 3. The first channel region CA1 may be a channel region of the first pull-down transistor PDT1. According to the operation of the first pull-down transistor PDT1, the third source/drain region SD3 and the first source/drain region SD1 may be connected to each other through the first channel region CA1. The negative voltage VBB may be applied to the third source/drain region SD3, and the first wordline enable signal NWIB1 may be applied to the first gate electrode 120.

The second gate electrode 130 may be disposed to be spaced apart from the first gate electrode 120 in the first direction D1. The second gate electrode 130 may be disposed between the first gate electrode 120 and the third gate electrode 140. The second gate electrode 130 may be disposed on the second channel region CA2. The second channel region CA2 may be defined as a region of the second active pattern AP2 that overlaps with the second gate electrode 130 in the fourth direction D4.

In some embodiments, the first source/drain region SD1, the second channel region CA2, and the second source/drain region SD2 may form the keeping transistor KPT of FIG. 3. The second channel region CA2 may be a channel region of the keeping transistor KPT. According to the operation of the keeping transistor KPT, the first source/drain region SD1 and the second source/drain region SD2 may be connected to each other through the second channel region CA2. The keeping transistor KPT and the first pull-down transistor PDT1 may share the first source/drain region SD1.

The first source/drain contact 150 may be disposed on the first source/drain region SD1. The first source/drain contact 150 may be connected to the first source/drain region SD1. The first source/drain contact 150 may be connected to the first wordline WL1 through a wiring structure 195. The first pull-up transistor PUT1 may be connected to the first source/drain region SD1.

The gate contact 160 may be disposed on the second gate electrode 130. The gate contact 160 may be formed through a gate capping pattern 114 to be described below and may be connected to the second gate electrode 130. The second driving signal PXIB may be applied to the second gate electrode 130 through the gate contact 160.

In some embodiments, the second channel region CA2 may extend in a third direction D3. The third direction D3 may be a direction different from each of the first and second directions D1 and D2. The first direction D1, the second direction D2, and the third direction D3 may be disposed on the same plane. All of the first, second, and third directions D1, D2, and D3 may be parallel to an upper surface of the substrate 100. The fourth direction D4 may be a direction perpendicular to each of the first, second, and third directions D1, D2, and D3. An angle between the third direction D3 and the first direction D1 may be an acute angle. The fourth direction D4 may be, for example, a thickness direction of the substrate 100. In other words, the first, second, and third directions D1, D2, and D3 may be horizontal directions, and the fourth direction D4 may be a vertical direction.

From a planar perspective, the second channel region CA2 may have a shape of a parallelogram.

The second channel region CA2 may include a first sidewall SW1 and a second sidewall SW2, which face the device isolation film 105. The first sidewall SW1 may be spaced apart from the second sidewall SW2 in the second direction D2. The first sidewall SW1 and the second sidewall SW2 may extend in the third direction D3. That is, an angle between the first sidewall SW1 and the first direction D1 and an angle between the second sidewall SW2 and the first direction D1 may be acute angles.

In some embodiments, the second active pattern AP2 may include a pair of recesses 115 disposed in an alternating fashion between the first channel region CA1 and the third channel region CA3. The pair of recesses 115 may define the second channel region CA2. For example, each of the pair of recesses 115 may be spaced apart from each other with the second channel region CA2 interposed therebetween. For example, a sidewall of each of the pair of recesses 115 may face the device isolation film 105. For example, the sidewall of the first recess of the pair of recesses 115 may include a portion of a sidewall of the first source/drain region SD1 and the second sidewall SW2 of the second channel region CA2. For example, the sidewall of the second recess of the pair of recesses 115 may include a portion of a sidewall of the second source/drain region SD2 and the first sidewall SW1 of the second channel region CA2.

The pair of recesses 115 may include a shape that is concave toward the second channel region CA2. In some embodiments, a width of each of the pair of recesses 115 in the second direction D2 may not be constant. For example, among the pair of recesses 115, the recess 115 adjacent to the first channel region CA1 in the second direction D2 may decrease in width as a distance from the first channel region CA1 increases, and among the pair of recesses 115, the recess 115 adjacent to the third channel region CA3 in the second direction D2 may decrease in width as a distance from the third channel region CA3 increases. For example, among the pair of recesses 115, the width of the recess 115 adjacent to the first channel region CA1 in the second direction D2 may remain constant and then decrease as the distance from the first channel region CA1 increases, and among the pair of recesses 115, the width of the recess 115 adjacent to the third channel region CA3 in the second direction D2 may remain constant and then decrease as the distance from the third channel region CA3 increases.

In some embodiments, the recess 115 may have a polygonal shape. For example, a portion of the recess 115 that overlaps with the second channel region CA2 in the second direction D2 may have a triangular shape, and a portion that overlaps with the source/drain regions SD1 and SD2 in the second direction D2 may have a rectangular shape. However, embodiments are not limited thereto. For example, the recess 115 may include only a triangular shape overlapping with the second channel region CA2 in the second direction D2. In addition, the shape of the recess 115 overlapping with the second channel region CA2 in the second direction D2 may have various shapes such as a square, a circle, and an ellipse.

FIG. 6 illustrates that one recess 115 and the other recess 115 do not overlap with each other in the first direction D1, but embodiments are not limited thereto. For example, the recess 115 may be more concave toward the second channel region CA2 than illustrated, so that at least a portion of one recess 115 may overlap the other recess 115 in the first direction D1.

The second gate electrode 130 may cover the second channel region CA2. The second gate electrode 130 may overlap with the second channel region CA2 in the fourth direction D4. In some embodiments, the shape of the second gate electrode 130 may correspond to the shape of the second channel region CA2. For example, the second gate electrode 130 may extend in the third direction D3. From a planar perspective, the second gate electrode 130 may have a shape of a parallelogram.

A length of a channel of the keeping transistor KPT may be greater than a width W1 of the second gate electrode 130 in the first direction D1. The length of the channel of the keeping transistor KPT may be the same as a width W2 of the second gate electrode 130 in the third direction D3.

As the memory cell of the DRAM becomes smaller, components of the core/periphery that control the operation of the memory cell need to be miniaturized. Miniaturizing the core/periphery transistor may reduce the channel length, which may increase the off-current of the transistor and lower the reliability of the semiconductor memory device.

On the other hand, in the sub wordline driver according to some embodiments, the channel region (e.g., channel region CA2) of the keeping transistor KPT may extend in the third direction D3. That is, the channel of the keeping transistor KPT may be oriented obliquely (e.g., in the third direction D3), which increases the length of the channel of the keeping transistor KPT. Accordingly, the electrical characteristics of the sub wordline drivers SWD1 and SWD2 and the semiconductor memory device including the same may be improved.

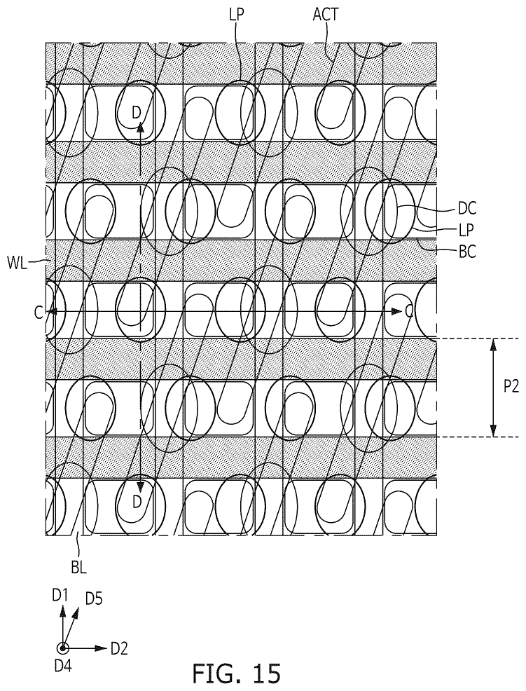

The second gate electrodes 130 may have a first pitch P1 in the first direction D1. The first pitch P1 may refer to spacing between same sides of the second gate electrodes 130 that are repeatedly disposed in the first direction D1. A distance of the first pitch P1 may be constrained within a certain range according to the number of wordlines (e.g., word lines WL in FIG. 15) connected to the sub wordline drivers SWD1 and SWD2. For example, it may be required that a value of the first pitch P1 be within 16 times a wordline pitch (e.g., wordline pitch P2 in FIG. 15) of the memory cell. However, embodiments are not limited thereto. The relationship between the first pitch P1 and the second pitch P2 is an example and it may vary according to a circuit design.

According to some embodiments, by obliquely arranging the channel of the keeping transistor KPT, the sub wordline drivers SWD1 and SWD2 may configure the keeping transistor KPT to have a longer channel relative to the same area. Accordingly, the area in which the keeping transistor KPT is disposed may be reduced, and the integration density of the sub wordline drivers SWD1 and SWD2 and the semiconductor memory device may be improved.

In some embodiments, the first source/drain region SD1 may be disposed between the first channel region CA1 and the second channel region CA2. The first source/drain region SD1 may include a first sub source/drain region SD1_P1 adjacent to the first channel region CA1 and a second sub source/drain region SD1_P2 adjacent to the second channel region CA2 (e.g., disposed between the first sub source/drain region SD1_P1 and the second channel region CA2). A width of the first sub source/drain region SD1_P1 in the second direction D2 may be greater than a width of the second sub source/drain region SD1_P2 in the second direction D2. In some embodiments, a width of the first source/drain region SD1 may decrease from the first channel region CA1 toward the second channel region CA2. For example, the sidewall of the first source/drain region SD1 may include a portion that faces the device isolation film 105 in the first direction D1.

In some embodiments, the second source/drain region SD2 may be disposed between the second channel region CA2 and the third channel region CA3. The second source/drain region SD2 may include a third sub source/drain region SD2_P1 adjacent to the third channel region CA3 and a fourth sub source/drain region SD2_P2 adjacent to a second channel region CA2(e.g., disposed between the third sub source/drain region SD2_P1 and the second channel region CA2). A width of the third sub source/drain region SD2_P1 in the second direction D2 may be greater than a width of the fourth sub source/drain region SD2_P2 in the second direction D2. In some embodiments, a width of the second source/drain region SD2 in the second direction D2 may decrease from the third channel region CA3 toward the second channel region CA2. For example, the sidewall of the second source/drain region SD2 may include a portion that faces the device isolation film 105 in the first direction D1. Widths of the third sub source/drain region SD2_P1 and the fourth sub source/drain region SD2_P2 of the second source/drain region SD2 may be the same as widths of the first sub source/drain region SD1_P1 and the second sub source/drain region SD1_P2, respectively, of the first source/drain region SD1.

In some embodiments, the first sidewall SW1 of the second channel region CA2 may include a portion that faces the second source/drain region SD2 in the first direction D1 with the device isolation film 105 interposed therebetween. In some embodiments, the second sidewall SW2 of the second channel region CA2 may include a portion that faces the first source/drain region SD1 in the first direction D1 with the device isolation film 105 interposed therebetween.

In some embodiments, the first channel region CA1 and the third channel region CA3 of the second active pattern AP2 may be aligned and overlapped with each other in the first direction D1. For example, at least a portion of the second channel region CA2 may overlap with each of the first channel region CA1 and the third channel region CA3 in the first direction D1. In this case, a width of the second channel region CA2 of the second active pattern AP2 in the second direction D2 may be less than a width of each of the first channel region CA1 and the third channel region CA3 in the second direction D2. In some embodiments, a portion of the second sub source/drain region SD1_P2 may overlap with the fourth sub source/drain region SD2_P2 in the first direction D1, while the remainder of the second sub source/drain region SD1_P2 may not overlap with the fourth sub source/drain region SD2_P2 in the first direction D1. For example, the second channel region CA2 may include a first side surface facing the first source/drain region SD1 and a second side surface facing the second source/drain region SD2, and the first side surface and the second side surface may at least partially overlap with each other in the first direction D1.

However, embodiments are not limited thereto. In some other embodiments, the first channel region CA1 and the third channel region CA3 of the second active pattern AP2 may not be aligned and overlapped with each other in the first direction D1, or may only partially be aligned and overlapped with each other. For example, the first channel region CA1 and the third channel region CA3 may be arranged in a horizontal direction that intersects with the first direction D1 and the second direction D2. For example, the second sub source/drain region SD1_P2 may not overlap with the fourth sub source/drain region SD2_P2 in the first direction D1.

The third gate electrode 140 may extend in the second direction D2 and may intersect with the second active pattern AP2. The third gate electrode 140 may be disposed to be spaced apart from the second gate electrode 130 in the first direction D1. The third gate electrode 140 may be disposed on the third channel region CA3. The third channel region CA3 may be defined as a region of the second active pattern AP2 that overlaps with the third gate electrode 140 in the fourth direction D4.

In some embodiments, the second source/drain region SD2, the third channel region CA3, and the fourth source/drain region SD4 may form the second pull-down transistor PDT2 of FIG. 3. The third channel region CA3 may be a channel region of the second pull-down transistor PDT2. The second source/drain region SD2 and the fourth source/drain region SD4 may be connected to each other through the third channel region CA3 according to the operation of the second pull-down transistor PDT2. The keeping transistor KPT and the second pull-down transistor PDT2 may share the second source/drain region SD2.

The second source/drain contact 170 may be disposed on the second source/drain region SD2. The second source/drain contact 170 may be connected to the second source/drain region SD2. The second source/drain contact 170 may be connected to the second wordline WL2 through the wiring structure 195. The second pull-up transistor PUT2 may be connected to the second source/drain region SD2. The negative voltage VBB may be applied to the fourth source/drain region SD4, and the second wordline enable signal NWIB2 may be applied to the third gate electrode 140.

The sub wordline driver according to some embodiments may be provided with a plurality of second active patterns AP2. For example, the second active patterns AP2 may be disposed to be spaced apart from each other in the second direction D2.

The shape of the second active pattern AP2 and the shape of the second active pattern AP2 adjacent thereto may be the same. The first gate electrode 120 may extend in the second direction D2 to intersect with the second active pattern AP2 and another second active pattern AP2 adjacent thereto. The third gate electrode 140 may extend in the second direction D2 to intersect with the second active pattern AP2 and another second active pattern AP2 adjacent thereto.

In some embodiments, a plurality of second gate electrodes 130 may be provided. For example, the number of second gate electrodes 130 may correspond to the number of second active patterns AP2. Specifically, the second gate electrode 130 may be disposed on the second active pattern AP2, and the another second gate electrode 130 may be disposed on another second active pattern AP2 adjacent to the second active pattern AP2. For the convenience of description, the second gate electrode 130 disposed in another second active pattern AP2 adjacent to the second active pattern AP2 is referred to as a fourth gate electrode 131, and a portion of another adjacent second active pattern AP2 that overlaps with the fourth gate electrode 131 in the fourth direction D4 is referred to as the fourth channel region CA4.

The fourth gate electrode 131 may be disposed to be spaced apart from the second gate electrode 130 in the second direction D2. The device isolation film 105 and an interlayer insulating film 180 may be disposed between the second gate electrode 130 and the fourth gate electrode 131. The second gate electrode 130 and the fourth gate electrode 131 may be aligned in the second direction D2. For example, the fourth gate electrode 131 may be disposed between the first gate electrode 120 and the third gate electrode 140. For example, each of the second gate electrode 130 and the fourth gate electrode 131 may extend in parallel in the second direction D2. Side surfaces of the second gate electrode 130 and the fourth gate electrode 131 facing each other may be parallel to each other.

In some embodiments, each of the first gate electrode 120 and the third gate electrode 140 may have a line shape. In some embodiments, the shapes of the second gate electrode 130 and the fourth gate electrode 131 may be the same as each other. For example, the second gate electrode 130 and the fourth gate electrode 131 may have an island shape. The island shape herein may refer to any shape surrounded by the interlayer insulating film 180. For example, the island shape may include shapes such as a dot shape, a parallelogram, a rectangle, a square, a rhombus, a circle, an ellipse, etc.

The fourth channel region CA4 may be disposed to be spaced apart from the second channel region CA2 in the second direction D2. The device isolation film 105 may be disposed between the second channel region CA2 and the fourth channel region CA4. The shape of the fourth channel region CA4 may be the same as the shape of the second channel region CA2. The fourth channel region CA4 may include a third sidewall SW3 and a fourth sidewall SW4 spaced apart from the third sidewall SW3 in the second direction D2. From a planar perspective, the second channel region CA2 and the fourth channel region CA4 may extend in parallel in the second direction D2 with the device isolation film 105 interposed therebetween. The second sidewall SW2 of the second channel region CA2 may face the third sidewall SW3 of the fourth channel region CA4. The second sidewall SW2 of the second channel region CA2 and the third sidewall SW3 of the fourth channel region CA4 may be parallel to each other.

In some embodiments, miniaturizing the semiconductor memory devices necessitates the miniaturization of the core/periphery components. As a result, unintended short circuit may occur due to contact between the gate electrode and the adjacent gate electrode. In the semiconductor memory device according to some embodiments, by arranging each of the second gate electrode 130 and the fourth gate electrode 131 adjacent thereto in the second direction D2 in a parallelogram shape, a distance between the second gate electrode 130 and the fourth gate electrode 131 may be increased. Accordingly, short circuit between the second gate electrode 130 and the fourth gate electrode 131 may be prevented, and the integration density of the sub wordline drivers and the semiconductor memory devices may be improved.

The first to third gate electrodes 120, 130, and 140 may have the same configuration. Hereinafter, the first gate electrode 120 will be primarily described as an example. The first gate electrode 120 may include a first conductive pattern 111 (e.g., a polysilicon layer), a barrier pattern 112 (e.g., a metal barrier layer), a second conductive pattern 113 (e.g., a metal layer), and the gate capping pattern 114 sequentially stacked on the substrate 100. For example, the barrier pattern 112 may contact an upper surface of the first conductive pattern 111, the second conductive pattern 113 may contact an upper surface of the barrier pattern 112, and the gate capping pattern 114 may contact an upper surface of the second conductive pattern 113. A gate insulating film 110 may be disposed between the first gate electrode 120 and the substrate 100. Specifically, the gate insulating film 110 may be disposed between the first conductive pattern 111 and the substrate 100. For example, the first conductive pattern 111 may contact an upper surface of the gate insulating film 110, and the gate insulating film 110 may contact an upper surface of the substrate 100. The first gate electrode 120 may be spaced apart from the substrate 100 by the gate insulating film 110. A pair of spacers 119 may be disposed on both sidewalls of the first gate electrode 120. The pair of spacers 119 may contact respective sidewalls of each of the gate insulating film 110, the first conductive pattern 111, the barrier pattern 112, the second conductive pattern 113, and the gate capping pattern 114.

The first conductive pattern 111 may include polysilicon or a doped semiconductor material. The first conductive pattern 111 may be formed of or include, for example, doped silicon, doped germanium, etc. The barrier pattern 112 may include a conductive metal nitride. The barrier pattern 112 may be formed of or include, for example, titanium nitride or tantalum nitride. The second conductive pattern 113 may include a metallic material. The second conductive pattern 113 may be formed of or include, for example, any one of titanium, tantalum, tungsten, copper, aluminum, or a combination thereof. The gate capping pattern 114 may include an insulating material. For example, the gate capping pattern 114 may be formed of or include silicon nitride, silicon oxynitride, silicon carbonitride, or silicon oxycarbonitride.

The gate insulating film 110 may include an insulating material. The gate insulating film 110 may be formed of or include, for example, silicon oxide. In some embodiments, the gate insulating film 110 may include a plurality of layers. For example, the gate insulating film 110 may include an interfacial film and a high-k insulating film stacked on the interfacial film. For example, the high-k insulating film may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate. The spacer 119 may include silicon oxide, silicon nitride, and/or silicon oxynitride.

The interlayer insulating film 180 may be formed on the substrate 100. The interlayer insulating film 180 may cover the first gate electrode 120, the second gate electrode 130, and the third gate electrode 140. The interlayer insulating film 180 may contact the first gate electrode 120, the second gate electrode 130, and the third gate electrode 140. For example, the interlayer insulating film 180 may include at least one of silicon oxide, silicon nitride, silicon oxynitride, and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof.

The first source/drain contact 150 may be formed through the interlayer insulating film 180 and connected to the first source/drain region SD1. The gate contact 160 may be formed through the interlayer insulating film 180 and a gate capping pattern 114, and connected to the second gate electrode 130. The second source/drain contact 170 may be formed through the interlayer insulating film 180 and connected to the second source/drain region SD2. The interlayer insulating film 180 may surround and contact each of the first source/drain contact 150, the second source/drain contact 170, and the gate contact 160. Each of the first source/drain contact 150, the second source/drain contact 170, and the gate contact 160 may include a conductive material. The conductive material may include, for example, titanium, tantalum, tungsten, copper, aluminum or molybdenum.

A wiring insulating film 190 may be disposed on the interlayer insulating film 180. The wiring structure 195 may be disposed in the wiring insulating film 190. The wiring structure 195 may be electrically connected to each of the first source/drain contact 150, the second source/drain contact 170, and the gate contact 160.

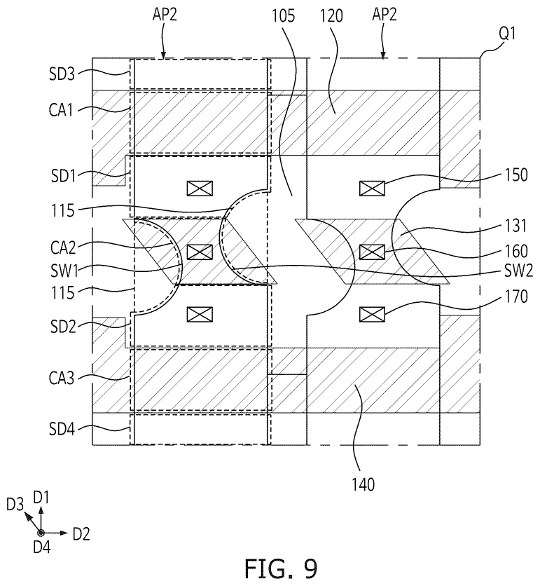

FIG. 9 is a diagram provided to explain a sub wordline driver according to some example embodiments. For the convenience of description, configurations different from those described in FIGS. 5 to 8 will be primarily described.

Referring to FIG. 9, in the sub wordline driver according to some embodiments, the second active pattern AP2 may include the pair of recesses 115 disposed in an alternating fashion between the first channel region CA1 and the third channel region CA3.

The pair of recesses 115 may define the second channel region CA2. The pair of recesses 115 may include a shape that is concave toward the second channel region CA2. Each of the pair of recesses 115 may have a semicircular shape. The recess 115 may be concave toward the second channel region CA2. Among the pair of recesses 115, the recess 115 adjacent to the first channel region CA1 may overlap with a portion of the first source/drain region SD1 and with the second channel region CA2 in the second direction D2. Among the pair of recesses 115, the recess 115 adjacent to the third channel region CA3 may overlap with a portion of the second source/drain region SD2 and with the second channel region CA2 in the second direction D2.

The second channel region CA2 may extend in the third direction D3. The width of the second channel region CA2 in the second direction D2 may not be constant. For example, the width of the second channel region CA2 in the second direction D2 may decrease and then increase as the distance from the first channel region CA1 increases. The second channel region CA2 may have a concave sidewall corresponding to the pair of recesses 115. For example, each of the first sidewall SW1 and the second sidewall SW2 of the second channel region CA2 may have a shape of a semicircular arc corresponding to the recess.

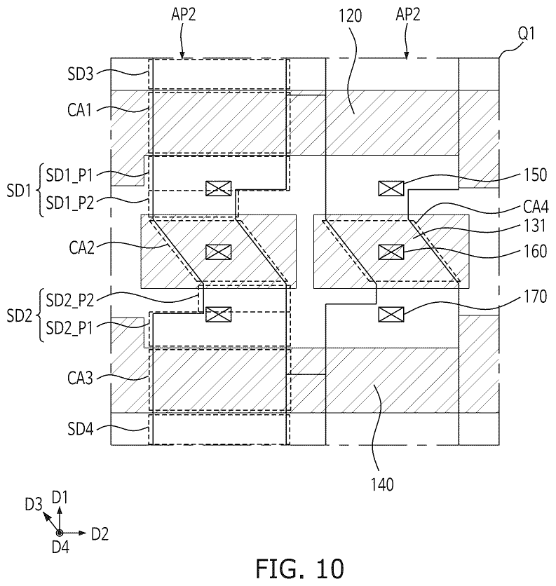

FIG. 10 is a diagram provided to explain the sub wordline driver according to some example embodiments. For the convenience of description, configurations different from those described in FIGS. 5 to 8 will be primarily described.

Referring to FIG. 10, in the sub wordline driver according to some embodiments, the shape of the second gate electrode 130 may be different from that of the second channel region CA2.

The second gate electrode 130 may extend in the second direction D2. From a planar perspective, the second gate electrode 130 may have a rectangular shape. The second gate electrode 130 may be disposed on the second channel region CA2 and the device isolation film 105. A portion of the second gate electrode 130 may overlap with the second channel region CA2 in the fourth direction D4, and the remainder of the second gate electrode 130 may overlap with the device isolation film 105 in the fourth direction D4.

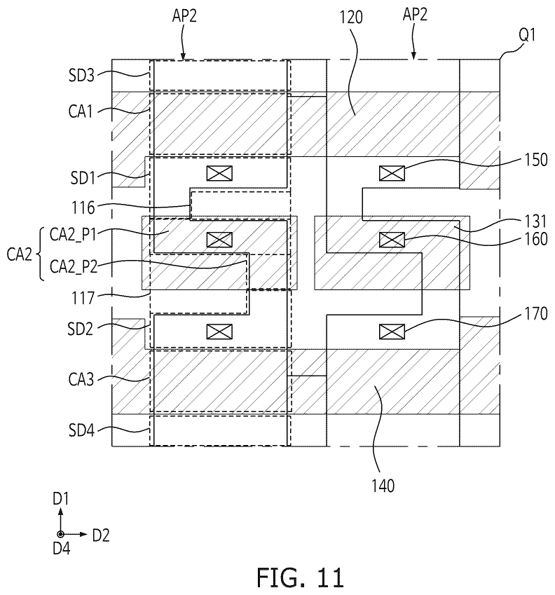

FIG. 11 is a diagram provided to explain the sub wordline driver according to some example embodiments. For the convenience of description, configurations different from those described in FIGS. 5 to 8 will be primarily described.

Referring to FIG. 11, in the sub wordline driver according to some embodiments, the second channel region CA2 may include a first sub channel region CA2_P1 and a second sub channel region CA2_P2.

The first sub channel region CA2_P1 may extend in the second direction D2. The first sub channel region CA2_P1 may be connected to the first source/drain region SD1. The second sub channel region CA2_P2 may extend in the first direction D1. The second sub channel region CA2_P2 may be connected to the second source/drain region SD2. The second sub channel region CA2_P2 may be disposed between the first sub channel region CA2_P1 and the second source/drain region SD2.

A width of the first sub channel region CA2_P1 in the second direction D2 may be greater than a width of the second sub channel region CA2_P2 in the second direction D2. From a planar perspective, the second channel region CA2 may have a shape similar to a rotated L-shape. The length of the channel of the keeping transistor (e.g., keeping transistor KPT in FIG. 3) may increase due to the shape of the second channel region CA2. For example, the length of the channel of the keeping transistor KPT may be greater than the width of the second gate electrode 130 in the first direction D1.

The second gate electrode 130 may be disposed on the second channel region CA2. The second gate electrode 130 may cover the second channel region CA2. Similar to FIG. 10, the second gate electrode 130 may have a rectangular shape. However, embodiments are not limited thereto.

In some embodiments, the second active pattern AP2 may include a first recess 116 and a second recess 117 disposed between the first channel region CA1 and the third channel region CA3. The first recess 116 and the second recess 117 may be disposed to be spaced apart from each other. For example, the first recess 116 and the second recess 117 may be spaced apart from each other in the first direction D1. The second channel region CA2 may be interposed between the first recess 116 and the second recess 117 spaced apart from each other in the first direction D1.

The first recess 116 may be disposed between the first source/drain region SD1 and the second channel region CA2. For example, the first recess 116 may be disposed between the first source/drain region SD1 and the first sub channel region CA2_P1. The first recess 116 may overlap with the second sub channel region CA2_P2 in the first direction D1.

The second recess 117 may be disposed between the second channel region CA2 and the second source/drain region SD2. For example, the second recess 117 may be disposed between the first sub channel region CA2_P1 and the second source/drain region SD2, and may be adjacent to the second sub channel region CA2_P2. The second recess 117 may not overlap with the second sub channel region CA2_P2 in the first direction D1.

The first recess 116 and the second recess 117 may be disposed in an alternating fashion. For example, directions in which the first recess 116 and the second recess 117 are concave may be different from each other. The first recess 116 and the second recess 117 each may include a rectangular shape. In some embodiments, a width of the first recess 116 in the first direction D1 and a width of the second recess 117 in the first direction D1 may be different from each other. However, embodiments are not limited thereto. The width of the first recess 116 in the first direction D1 may be the same as the width of the second recess 117 in the first direction D1. A width of the first recess 116 in the second direction D2 may be the same as a width of the second recess 117 in the second direction D2. However, embodiments are not limited thereto. The width of the first recess 116 in the second direction D2 and the width of the second recess 117 in the second direction D2 may be different from each other.

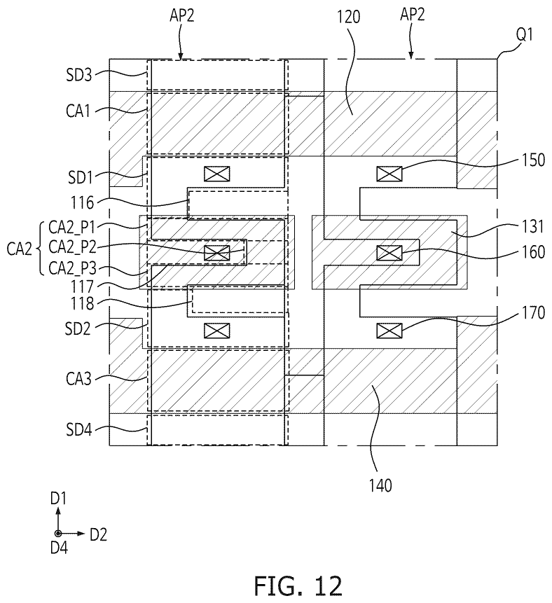

FIG. 12 is a diagram provided to explain a sub wordline driver according to some example embodiments. For the convenience of description, configurations different from those described in FIGS. 5 to 8 will be primarily described.

Referring to FIG. 12, in the sub wordline driver according to some embodiments, the second channel region CA2 may include the first sub channel region CA2_P1, the second sub channel region CA2_P2, and a third sub channel region CA2_P3.

The first sub channel region CA2_P1 may extend in the second direction D2. The first sub channel region CA2_P1 may be connected to the first source/drain region SD1. The second sub channel region CA2_P2 may extend in the first direction D1. The second sub channel region CA2_P2 may be connected to the first sub channel region CA2_P1. The third sub channel region CA2_P3 may extend in the second direction D2. The third sub channel region CA2_P3 may be connected to the second sub channel region CA2_P2.

The width of the first sub channel region CA2_P1 in the second direction D2 may be greater than the width of the second sub channel region CA2_P2 in the second direction D2. A width of the third sub channel region CA2_P3 in the second direction D2 may be greater than the width of the second sub channel region CA2_P2 in the second direction D2. In some embodiments, the width of the first sub channel region CA2_P1 in the second direction D2 may be the same as the width of the third sub channel region CA2_P3 in the second direction D2.

From a planar perspective, the second channel region CA2 may have a shape similar to a rotated U-shape. The length of the channel of the keeping transistor (e.g., keeping transistor KPT in FIG. 3) may increase due to the shape of the second channel region CA2. For example, the length of the channel of the keeping transistor KPT may be greater than the width of the second gate electrode 130 in the first direction D1.

The second gate electrode 130 may be disposed on the second channel region CA2. The second gate electrode 130 may cover the second channel region CA2. Similar to FIG. 10, the second gate electrode 130 may have a rectangular shape. However, embodiments are not limited thereto.

In some embodiments, the second active pattern AP2 may include the first recess 116, the second recess 117, and a third recess 118 disposed between the first channel region CA1 and the third channel region CA3.

The first recess 116 may be disposed between the first source/drain region SD1 and the second channel region CA2. For example, the first recess 116 may be disposed between the first source/drain region SD1 and the first sub channel region CA2_P1. The first recess 116 may overlap with the second sub channel region CA2_P2 in the first direction D1.

The second recess 117 may be disposed on the second channel region CA2. For example, the second recess 117 may be disposed between the first sub channel region CA2_P1 and the third sub channel region CA2_P3. The second channel region CA2 may surround a portion of the second recess 117. For example, the second channel region CA2 may surround three surfaces of the second recess 117. The second recess 117 may overlap with the second channel region CA2 in the second direction D2. The second recess 117 may be disposed between the first recess 116 and the third recess 118.

The third recess 118 may be disposed between the second channel region CA2 and the second source/drain region SD2. For example, the third recess 118 may be disposed between the third sub channel region CA2_P3 and the second source/drain region SD2. The third recess 118 may overlap with the second sub channel region CA2_P2 in the first direction D1.

The first recess 116 and the second recess 117 may be disposed in an alternating fashion. For example, directions in which the first recess 116 and the second recess 117 are concave may be different from each other. The second recess 117 and the third recess 118 may be disposed in an alternating fashion. For example, directions in which the second recess 117 and the third recess 118 are concave may be different from each other. The directions in which the first recess 116 and the third recess 118 are concave may be the same as each other. The first recess 116 may overlap with the third recess 118 in the first direction D1.

Each of the first recess 116, the second recess 117, and the third recess 118 may have a rectangular shape. In some embodiments, the widths of each of the first recess 116, the second recess 117, and the third recess 118 in the first direction D1 and the second direction D2 may be the same, partially same, or different from each other.

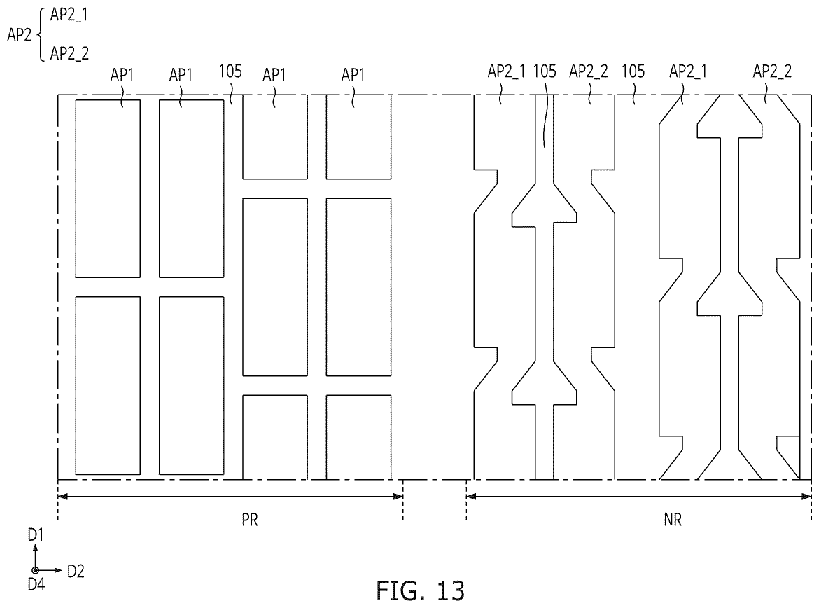

FIG. 13 is a diagram provided to explain the sub wordline driver according to some example embodiments. For the convenience of description, configurations different from those described in FIGS. 5 to 8 will be primarily described.

Referring to FIG. 13, the sub wordline driver according to some embodiments may include a PMOS region PR and an NMOS region NR.

The PMOS region PR may be a region where the PMOSFET is disposed, and the NMOS region NR may be a region where the NMOSFET is disposed. The first active pattern AP1 may be disposed on the PMOS region PR, and the second active pattern AP2 may be disposed on the NMOS region NR.

In some embodiments, two second active patterns AP2 may be disposed in pairs. For example, a pair of second active patterns AP2 may include a first sub active pattern AP2_1 and a second sub active pattern AP2_2. The first sub active pattern AP2_1 and the second sub active pattern AP2_2 may be symmetrically disposed with respect to the first direction D1.

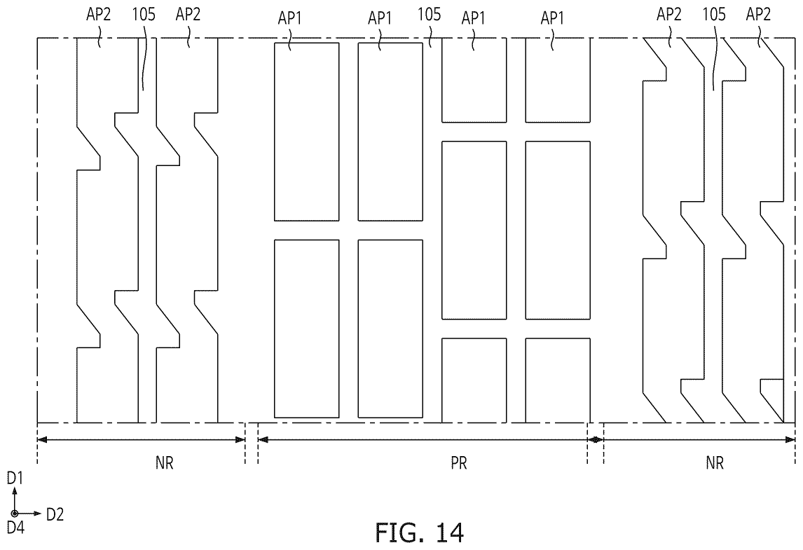

FIG. 14 is a diagram provided to explain a sub wordline driver according to some example embodiments. For the convenience of description, configurations different from those described in FIGS. 5 to 8 will be primarily described.

Referring to FIG. 14, the sub wordline driver according to some embodiments may include the PMOS region PR and the NMOS region NR.

The pair of second active patterns AP2 may be disposed on the NMOS regions NR. The pair of second active patterns AP2 may refer to the second active patterns AP2 aligned in the second direction D2. The pair of first active patterns AP1 may be disposed to be spaced apart from each other in the first direction D1.

The PMOS region PR may be disposed to be spaced apart from the NMOS regions NR in the second direction D2. The PMOS region PR may be disposed between the NMOS region NR and the NMOS region NR adjacent thereto. In some embodiments, the transistor on the NMOS region NR may be connected to the transistor disposed on the pair of first active patterns AP1 in the adjacent PMOS region PR.

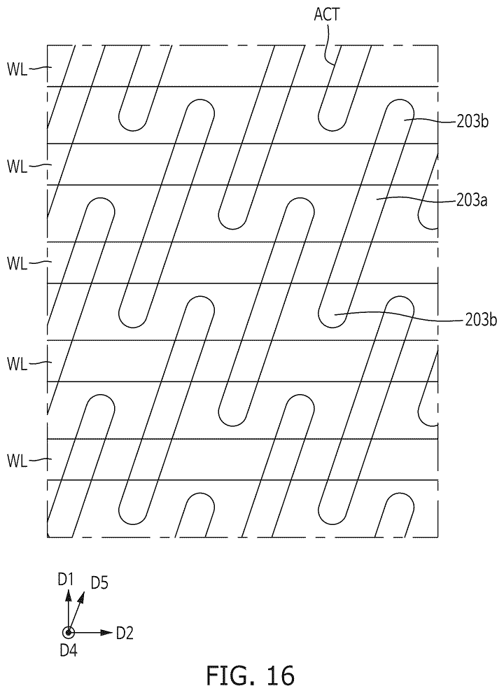

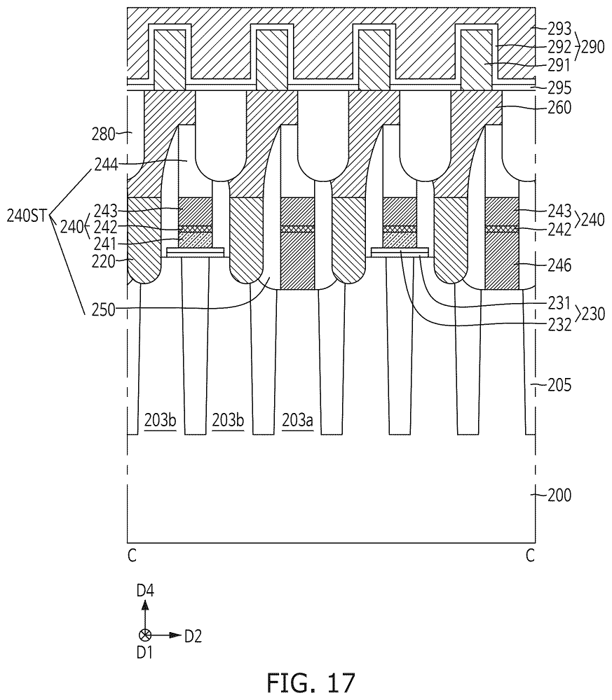

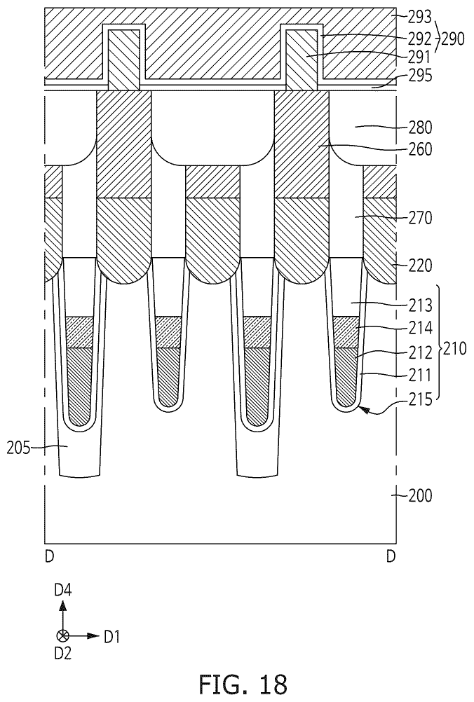

FIG. 15 is a plan view provided to explain a memory cell of a semiconductor device according to some example embodiments. FIG. 16 is a plan view provided to explain a memory cell of a semiconductor device according to some example embodiments. FIG. 17 is a cross-sectional view taken along line C-C of FIG. 15. FIG. 18 is a cross-sectional view taken along line D-D of FIG. 15. The semiconductor memory device illustrated in FIGS. 15 to 18 may correspond to the memory cell disposed on the cell region CELL of FIG. 1.

Referring to FIGS. 15 and 16, the semiconductor memory device according to some embodiments may include a plurality of cell active regions ACT.

The cell active region ACT may be defined by a cell device isolation film 205 formed in a substrate (e.g., substrate 200 in FIG. 17). As the design rules of the semiconductor memory device decrease, the cell active region ACT may be disposed in the form of a bar of a diagonal line or an oblique line as illustrated. For example, the cell active region ACT may extend lengthwise in a fifth direction D5.

A plurality of gate electrodes extending in the second direction D2 across the cell active region ACT may be disposed. The plurality of gate electrodes may extend parallel to each other. The plurality of gate electrodes may be, for example, a plurality of wordlines WL. The wordlines WL may be disposed at equal intervals. A width of the wordline WL or an interval between the wordlines WL may be determined according to design rules.

Each of the cell active regions ACT may be divided into three parts by two wordlines WL extending in the second direction D2. The cell active region ACT may include a storage connection portion 203b and a bit line connection portion 203a. The bit line connection portion 203a may be disposed at a center of the cell active region ACT, and the storage connection portion 203b may be disposed at an end of the cell active region ACT.

For example, the bit line connection portion 203a may be a region connected to the bit line BL, and the storage connection portion 203b may be a region connected to an information storage unit (e.g., information storage unit 290 in FIG. 17). In other words, the bit line connection portion 203a may correspond to the common drain region, and the storage connection portion 203b may correspond to the source region. Each wordline WL, along with the bit line connection portion 203a and the storage connection portion 203b adjacent thereto, may form a transistor.

A plurality of bit lines BL extending in the first direction D1 orthogonal to the wordline WL may be disposed on the wordline WL. The plurality of bit lines BL may extend parallel to each other. The bit lines BL may be disposed at equal intervals. A width of the bit line BL or an interval between the bit lines BL may be determined according to design rules. The bit lines BL may correspond to the bit line structures 240ST of FIG. 17.

The fourth direction D4 may be orthogonal to the second direction D2, the first direction D1, and the fifth direction D5. The fourth direction D4 may be a thickness direction of the substrate 100. The first direction D1, the second direction D2, and the fifth direction D5 may be parallel to the upper surface of the substrate 100.

The semiconductor memory device according to some embodiments may include various contact arrangements formed on the cell active region ACT. Various contact arrangements may include, for example, direct contacts (DC), buried contacts (BC), landing pads (LP), etc.

The direct contact DC may refer to a contact for electrically connecting the cell active region ACT to the bit line BL. The buried contact BC may refer to a contact for connecting the cell active region ACT to a lower electrode (e.g., lower electrode 291 in FIG. 17) of the capacitor. Due to the arrangement structure, the contact area between the buried contact BC and the cell active region ACT may be small. Accordingly, a conductive landing pad LP may be introduced to increase both a contact area with the cell active region ACT and a contact area with the lower electrode (e.g., lower electrode 291 in FIG. 17) of the capacitor.

The landing pad LP may be disposed between the cell active region ACT and the buried contact BC, or between the buried contact BC and the lower electrode (e.g., lower electrode 291 in FIG. 17) of the capacitor. In the semiconductor memory device according to some embodiments, the landing pad LP may be disposed between the buried contact BC and the lower electrode of the capacitor. By increasing the contact area through the introduction of the landing pad LP, the contact resistance between the cell active region ACT and the capacitor lower electrode may decrease.

The direct contact DC may be connected to the bit line connection portion 203a. The buried contact BC may be connected to the storage connection portion 203b. As the buried contact BC is disposed at both ends of the cell active region ACT, the landing pad LP may be disposed adjacent to both ends of the cell active region ACT to partially overlap with the buried contact BC. In other words, the buried contact BC may be formed to overlap with the cell active region ACT and the cell device isolation film (e.g., cell device isolation film 205 in FIG. 17) between adjacent wordlines WL and between adjacent bit lines BL.

The wordline WL may be formed as a buried structure within the substrate 200. The wordline WL may be disposed across the cell active region ACT between the direct contacts DC or the buried contacts BC. As illustrated, two wordlines WL may be disposed across one cell active region ACT. With the cell active region ACT extending in the fifth direction D5, the wordline WL may form an angle of less than 90 degrees with the cell active region ACT.

The direct contact DC and the buried contact BC may be disposed symmetrically with respect to each other. Accordingly, the direct contact DC and the buried contact BC may be disposed on a straight line along the second direction D2 and the first direction D1. Meanwhile, unlike the direct contact DC and the buried contact BC, the landing pad LP may be disposed in a zigzag shape in the first direction D1 in which the bit line BL extends. In addition, the landing pad LP may be disposed to overlap with the same side portion of each bit line BL in the second direction D2 in which the wordline WL extends.

For example, each of the landing pads LP of the first line may overlap with the left side of the corresponding bit line BL, and each of the landing pads LP of the second line may overlap with the right side of the corresponding bit line BL.

Referring to FIGS. 15 to 18, the semiconductor memory device according to some embodiments may include a plurality of cell gate structures 210, a plurality of bit line structures 240ST, a plurality of bit line contacts 246, and the information storage unit 290.

The substrate 200 may be a silicon substrate or a silicon-on-insulator (SOI). Alternatively, the substrate 200 may include silicon germanium, silicon germanium on insulator (SGOI), indium antimony, lead tellurite compound, indium arsenic, indium phosphide, gallium arsenic, or gallium antimony, but is not limited thereto.

The cell device isolation film 205 may be formed in the substrate 200. The cell device isolation film 205 may have a shallow trench isolation (STI) structure having excellent device isolation characteristics. The cell device isolation film 205 may define the cell active region ACT in a memory cell region.

As illustrated in FIGS. 15 and 16, the cell active region ACT defined by the cell device isolation film 205 may have a long island shape that includes a short axis and a long axis. The cell active region ACT may have an oblique shape that forms an angle of less than 90 degrees with respect to the wordline WL formed in the cell device isolation film 205. In addition, the cell active region ACT may have an oblique shape that forms an angle of less than 90 degrees with respect to the bit line BL formed on the cell device isolation film 205.

The cell device isolation film 205 may include at least one of silicon oxide, silicon nitride, and silicon oxynitride, but is not limited thereto.

Although it is illustrated herein that the cell device isolation film 205 includes one insulating film, this is only for the convenience of description, and embodiments are not limited thereto. According to the distance between the adjacent cell active regions ACT, the cell device isolation film 205 may include one insulating film or a plurality of insulating films.

The cell gate structure 210 may be formed in the substrate 100 and the cell device isolation film 205. The cell gate structure 210 may be formed across the cell active region ACT defined by the cell device isolation film 205 and the cell device isolation film 205.

The cell gate structure 210 is formed in the substrate 100 and the cell device isolation film 205. The cell gate structure 210 may include a cell gate trench 215, a cell gate insulating film 211, a cell gate electrode 212, a cell gate capping pattern 213, and a cell gate conductive film 214.

The cell gate electrode 212 may correspond to the wordline WL. For example, the cell gate electrode 212 may be the wordline WL of FIG. 15. Unlike the illustration, the cell gate structure 210 may not include the cell gate conductive film 214.

The cell gate insulating film 211 may extend along a sidewall and a bottom surface of the cell gate trench 215. The cell gate insulating film 211 may extend along a profile of at least a portion of the cell gate trench 215.

The cell gate insulating film 211 may include at least one of, for example, silicon oxide, silicon nitride, silicon oxynitride, or a high-k material having a dielectric constant higher than silicon oxide. For example, the high-k material may include at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination of thereof.

The cell gate electrode 212 may be disposed on the cell gate insulating film 211. The cell gate electrode 212 may partially fill the cell gate trench 215. The cell gate electrode 212 may be surrounded by the cell gate insulating film 211.

The cell gate electrode 212 may include at least one of a metal, a metal alloy, a conductive metal nitride, a conductive metal carbonitride, a conductive metal carbide, a metal silicide, a doped semiconductor material, a conductive metal oxynitride, and a conductive metal oxide. For example, the cell gate electrode 212 may include at least one of TiN, TaC, TaN, TiSiN, TaSiN, TaTiN, TiAlN, TaAlN, WN, Ru, TiAl, TiAlC-N, TiAlC, TiC, TaCN, W, Al, Cu, Co, Ti, Ta, Ni, Pt, Ni-Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, and a combination thereof, but is not limited thereto.

The cell gate conductive film 214 may be disposed on the cell gate electrode 212. The cell gate conductive film 214 may extend along an upper surface of the cell gate electrode 212. The cell gate conductive film 214 may cover the upper surface of the cell gate electrode 212. The cell gate conductive film 214 may contact the upper surface of the cell gate electrode 212. The cell gate conductive film 214 may overlap with the cell gate electrode 212 in the fourth direction D4. Both sidewalls of the cell gate conductive film 214 may be in contact with the cell gate insulating film 211. The cell gate conductive film 214 may be surrounded by the cell gate insulating film 211.

The cell gate conductive film 214 may include a semiconductor material. For example, the cell gate conductive film 214 may include one of polysilicon, polysilicon-germanium, amorphous silicon, and amorphous silicon-germanium, but is not limited thereto.

In some embodiments, the cell gate conductive film 214 may include N-type impurities. In an example, the concentration of the N-type impurities of the cell gate conductive film 214 may be constant. In another example, the concentration of the N-type impurities of the cell gate conductive film 214 may be greater in the upper portion than in the lower portion. For example, the N-type impurities may include at least one of phosphorus (P), arsenic (As), antimony (Sb), and bismuth (Bi). However, embodiments are not limited thereto.

The cell gate capping pattern 213 may be disposed on the cell gate electrode 212 and the cell gate conductive film 214. The cell gate capping pattern 213 may contact an upper surface of the cell gate conductive film 214. The cell gate capping pattern 213 may fill the remaining cell gate trench 215 after the cell gate electrode 212 and the cell gate conductive film 214 have been formed. It is illustrated that the cell gate insulating film 211 extends along the sidewall of the cell gate capping pattern 213, but embodiments are not limited thereto.

For example, the cell gate capping pattern 213 may include at least one of silicon nitride (SiN), silicon oxynitride (SiON), silicon oxide (SiO₂), silicon carbonitride (SiCN), silicon oxycarbonitride (SiOCN), and a combination thereof.

FIG. 18 illustrates that an upper surface of the cell gate capping pattern 213 is placed on the same plane as an upper surface of the cell device isolation film 205, but embodiments are not limited thereto.

As illustrated in FIG. 17, an impurity doped region may be formed on at least one side of the cell gate structure 210. The impurity doped region may be a source/drain region of the transistor. The impurity doped region may correspond to the storage connection portion 203b and the bit line connection portion 203a of FIG. 15.

In FIG. 16, if the transistor including each wordline WL, the bit line connection portion 203a and the storage connection portion 203b adjacent thereto is an NMOS, the storage connection portion 203b and the bit line connection portion 203a may include at least one of doped n-type impurities such as, for example, phosphorus (P), arsenic (As), antimony (Sb), and bismuth (Bi). If the transistor including each wordline WL, the bit line connection portion 203a and the storage connection portion 203b adjacent thereto is a PMOS, the storage connection portion 203b and the bit line connection portion 203a may include doped p-type impurities such as, for example, boron (B).

A bit line structure 240ST may include a cell conductive line 240, a cell line capping film 244, and a bit line spacer 250.

The cell conductive line 240 may be disposed on the substrate 200 and the cell device isolation film 205 in which the cell gate structure 210 is formed. The cell conductive line 240 may intersect with the cell active region ACT defined by the cell device isolation film 205 and the cell device isolation film 205. The cell conductive line 240 may be formed to intersect with the cell gate structure 210. The cell conductive line 240 may correspond to the bit line BL. For example, the cell conductive line 240 may be the bit line BL of FIG. 15.

For example, the cell conductive line 240 may include at least one of an impurity-doped semiconductor material, a conductive silicide compound, a conductive metal nitride, a two-dimensional (2D) material, a metal, and a metal alloy. In the semiconductor memory device according to some embodiments, the 2D material may be a metallic material and/or a semiconductor material. The 2D material may include a 2D allotrope or a 2D compound, and may include, for example, at least one of graphene, molybdenum disulfide (MoS₂), molybdenum diselenide (MoSe₂), tungsten diselenide (WSe₂), and tungsten disulfide (WS₂), but is not limited thereto. That is, since the 2D materials listed above are only examples, the 2D materials that may be included in the semiconductor memory device of the present disclosure are not limited to those mentioned above.

Although the cell conductive line 240 is illustrated as a single film, this is only for the convenience of description, and embodiments are not limited thereto. That is, unlike the illustration, the cell conductive line 240 may include a plurality of conductive films in which a conductive material is stacked.

The cell line capping film 244 may be disposed on the cell conductive line 240. The cell line capping film 244 may extend along an upper surface of the cell conductive line 240 in the first direction D1. For example, the cell line capping film 244 may include at least one of silicon nitride, silicon oxynitride, silicon carbonitride, and silicon oxycarbonitride.

In the semiconductor memory device according to some embodiments, the cell line capping film 244 may include silicon nitride. The cell line capping film 244 is illustrated as a single film, but is not limited thereto.

The bit line spacer 250 may be disposed on sidewalls of the cell conductive line 240 and the cell line capping film 244. The bit line spacer 250 extends along in the first direction D1.

Although the bit line spacer 250 is illustrated as a single film, this is only for the convenience of description, and embodiments are not limited thereto. That is, unlike the illustration, it goes without saying that the bit line spacer 250 may have a multilayer structure. For example, the bit line spacer 250 may include one of silicon oxide, silicon nitride, silicon oxynitride (SiON), silicon oxycarbonitride (SiOCN), air, and a combination thereof, but is not limited thereto.

A cell insulating film 230 may be formed on the substrate 100 and the cell device isolation film 205. More specifically, the cell insulating film 230 may be formed on the upper surfaces of the substrate 100 and the cell device isolation film 205 where the bit line contact 246 and a storage contact 220 have not been formed. The cell insulating film 230 may be formed between the substrate 100 and the cell conductive line 240, and between the cell device isolation film 205 and the cell conductive line 240.

The cell insulating film 230 may be a single film, but as illustrated, the cell insulating film 230 may be a multi-film including a first cell insulating film 231 and a second cell insulating film 232. For example, the first cell insulating film 231 may include silicon oxide, and the second cell insulating film 232 may include silicon nitride, but embodiments are not limited thereto. Unlike the illustration, the cell insulating film 230 may be a triple layer including silicon oxide, silicon nitride, and silicon oxide, but embodiments are not limited thereto.

The bit line contact 246 may be formed between the cell conductive line 240 and the substrate 200. The cell conductive line 240 may be disposed on the bit line contact 246. The cell conductive line 240 may include a first cell conductive layer 241, a second cell conductive layer 242, and a third cell conductive layer 243. For example, the third cell conductive layer 243 may be formed on and contact an upper surface of the second cell conductive layer 242, and the second cell conductive layer 242 may be formed on and contact an upper surface of the first cell conductive layer 241.

The bit line contact 246 may be formed between the bit line connection portion 203a of the cell active region ACT and the cell conductive line 240. The bit line contact 246 may electrically connect the cell conductive line 240 to the substrate 200. The bit line contact 246 may be connected to the bit line connection portion 203a. For example, the bit line contact 246 may contact the bit line connection portion 203a.

The bit line contact 246 may include an upper surface connected to the cell conductive line 240. For example, the bit line contact 246 may contact the upper surface connected to the cell conductive line 240. Although it is illustrated herein that the width of the bit line contact 246 in the second direction D2 remains constant regardless of the distance from the upper surface of the bit line contact 246, this is only for the convenience of description, and embodiments are not limited thereto.

The bit line contact 246 may correspond to the direct contact DC. For example, the bit line contact 246 may include at least one of an impurity-doped semiconductor material, a conductive metal silicide, a conductive metal nitride, a conductive metal oxide, a metal, and a metal alloy.

In a portion of the cell conductive line 240 where the bit line contact 246 is formed, the bit line spacer 250 may be formed on the substrate 200 and the cell device isolation film 205. The bit line spacer 250 may be disposed on the sidewalls of the cell conductive line 240, the cell line capping film 244, and the bit line contact 246. For example, the bit line spacer 250 may contact the sidewalls of the cell conductive line 240, the cell line capping film 244, and the bit line contact 246.

In the remaining portion of the cell conductive line 240 where the bit line contact 246 has not been formed, the bit line spacer 250 may be disposed on the cell insulating film 230. The bit line spacer 250 may be disposed on the sidewalls of the cell conductive line 240 and the cell line capping film 244. In the remaining portion of the cell conductive line 240 where the bit line contact 246 has not been formed the first cell conductive layer 241 may be formed to contact an upper surface of the cell insulating film 230.

A fence pattern 270 may be disposed on the substrate 200 and the cell device isolation film 205. The fence pattern 270 may be formed to overlap with the cell gate structure 210 formed in the substrate 200 and the cell device isolation film 205.

The fence pattern 270 may be disposed between the bit line structures 240ST extending in the first direction D1. For example, the fence pattern 270 may include at least one of silicon oxide, silicon nitride, silicon oxynitride, and a combination thereof.

The storage contact 220 may be disposed between the cell conductive lines 240 adjacent to each other in the second direction D2. The storage contacts 220 may be disposed on both sides of the cell conductive line 240. More specifically, the storage contact 220 may be disposed between the bit line structures 240ST. The storage contact 220 may be disposed between adjacent fence patterns 270 in the first direction D1.

The storage contact 220 may overlap with the substrate 100 and the cell device isolation film 205 between adjacent cell conductive lines 240. The storage contact 220 may be connected to the cell active region ACT. More specifically, the storage contact 220 may be connected to the storage connection portion 203b. The storage contact 220 may correspond to the buried contact BC of FIG. 14.

For example, the storage contact 220 may include at least one of an impurity-doped semiconductor material, a conductive silicide compound, a conductive metal nitride, and a metal.

A storage pad 260 may be formed on the storage contact 220. The storage pad 260 may contact an upper surface of the storage contact 220. The storage pad 260 may be electrically connected to the storage contact 220. It may be connected to the storage connection portion 203b of the cell active region ACT. The storage pad 260 may correspond to the landing pad LP.

The storage pad 260 may overlap with a portion of an upper surface of the bit line structure 240ST. For example, the storage pad 260 may include at least one of a conductive metal nitride, a conductive metal carbide, a metal, and a metal alloy.

A pad isolation insulating film 280 may be formed on the storage pad 260 and the bit line structure 240ST. The pad isolation insulating film 280 may contact the storage pad 260 and the fence patterns 270. For example, the pad isolation insulating film 280 may be disposed on the cell line capping film 244. The pad isolation insulating film 280 may define the storage pad 260 that forms a plurality of isolation regions. The pad isolation insulating film 280 may not cover an upper surface of the storage pad 260. For example, based on the upper surface of the substrate 200, a height of the upper surface of the storage pad 260 may be the same as a height of an upper surface of the pad isolation insulating film 280.

The pad isolation insulating film 280 may include an insulating material and may electrically separate a plurality of storage pads 260 from each other. For example, the pad isolation insulating film 280 may include at least one of, for example, silicon oxide, silicon nitride, silicon oxynitride, silicon oxycarbonitride, and silicon carbonitride.

An etching stop film 295 may be disposed on the upper surface of the storage pad 260 and the upper surface of the pad isolation insulating film 280. The etching stop film 295 may contact the upper surface of the storage pad 260 and the upper surface of the pad isolation insulating film 280. For example, the etching stop film 295 may include at least one of silicon nitride (SiN), silicon carbonitride (SiCN), silicon oxycarbonitride (SiOCN), silicon oxide carbonate (SiOC), and silicon boron nitride (SiBN).

The information storage unit 290 may be formed on the storage pad 260. The information storage unit 290 is connected to the storage pad 260. A portion of the information storage unit 290 may be disposed in the etching stop film 295.

The information storage unit 290 may include, for example, a capacitor, but is not limited thereto. The information storage unit 290 includes the lower electrode 291, a capacitor dielectric film 292, and an upper electrode 293. For example, the upper electrode 293 may be a plate upper electrode that has a plate shape.

The lower electrode 291 may be disposed on the storage pad 260. The lower electrode 291 may have, for example, a pillar shape.

The capacitor dielectric film 292 is formed on the lower electrode 291. The capacitor dielectric film 292 may be formed according to a profile of the lower electrode 291. The upper electrode 293 is formed on the capacitor dielectric film 292. The upper electrode 293 may surround an outer wall of the lower electrode 291. Although the upper electrode 293 is illustrated as a single film, this is only for the convenience of description, and embodiments are not limited thereto.

The lower electrode 291 and the upper electrode 293 may include, for example, a doped semiconductor material, a conductive metal nitride (e.g., titanium nitride, tantalum nitride, niobium nitride, tungsten nitride, etc.), a metal (e.g., lucenium, iridium, titanium, tantalum, etc.), and a conductive metal oxide (e.g., iridium oxide or niobium oxide, etc.), but is not limited thereto.

The capacitor dielectric film 292 may include one of, for example, silicon oxide, silicon nitride, silicon oxynitride, a high-k material, and a combination thereof, but is not limited thereto. In the semiconductor memory device according to some embodiments, the capacitor dielectric film 292 may include a stacked layer structure in which zirconium oxide, aluminum oxide, and zirconium oxide are sequentially stacked. In the semiconductor memory device according to some embodiments, the capacitor dielectric film 292 may include a dielectric film including hafnium (Hf). In the semiconductor memory device according to some embodiments, the capacitor dielectric film 292 may have a stacked film structure of a ferroelectric material film and a phase dielectric material film.

Although certain embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

1. A sub wordline driver, comprising:
a substrate comprising an active pattern, wherein the active pattern comprises a first channel region, a second channel region, and a third channel region, which are disposed to be sequentially spaced apart in a first horizontal direction;
a first gate electrode disposed on the first channel region and extending in a second horizontal direction perpendicular to the first horizontal direction;
a second gate electrode disposed on the second channel region; and
a third gate electrode disposed on the third channel region and extending in the second horizontal direction,
wherein the second channel region extends in a third horizontal direction that forms an acute angle with the first horizontal direction, and a width of the second channel region in the third horizontal direction is greater than a width of the second channel region in the first horizontal direction.

2. The sub wordline driver according to claim 1,
wherein the active pattern comprises a pair of recesses disposed in an alternating fashion between the first channel region and the third channel region, and
wherein the second channel region is disposed between the pair of recesses.

3. The sub wordline driver according to claim 2,
wherein among the pair of recesses, a width of a recess adjacent to the first channel region in the second horizontal direction decreases as a distance from the first channel region increases, and
wherein among the pair of recesses, a width of a recess adjacent to the third channel region in the second horizontal direction decreases as a distance from the third channel region increases.

4. The sub wordline driver according to claim 2, wherein among the pair of recesses, a width of a recess in the second horizontal direction is not constant.

5. The sub wordline driver according to claim 1,
wherein each of the first gate electrode and the third gate electrode has a line shape, and
wherein the second gate electrode has an island shape.

6. The sub wordline driver according to claim 1,
wherein the active pattern further comprises a first source/drain region disposed between the first channel region and the second channel region,
wherein the first source/drain region comprises a first sub source/drain region adjacent to the first channel region and a second sub source/drain region disposed between the first sub source/drain region and the second channel region, and
wherein a width of the first sub source/drain region in the second horizontal direction is greater than a width of the second sub source/drain region in the second horizontal direction.

7. The sub wordline driver according to claim 6,
wherein the active pattern further comprises a second source/drain region disposed between the second channel region and the third channel region,
wherein the second source/drain region comprises a third sub source/drain region adjacent to the third channel region and a fourth sub source/drain region disposed between the third sub source/drain region and the second channel region, and
wherein a width of the third sub source/drain region in the second horizontal direction is greater than a width of the fourth sub source/drain region in the second horizontal direction.

8. The sub wordline driver according to claim 7,
wherein a portion of the second sub source/drain region overlaps with the fourth sub source/drain region in the first horizontal direction, and
wherein a remaining portion of the second sub source/drain region does not overlap with the fourth sub source/drain region in the first horizontal direction.

9. The sub wordline driver according to claim 1, wherein a width of the first channel region in the second horizontal direction is greater than a width of the second channel region in the second horizontal direction.

10. The sub wordline driver according to claim 1, further comprising:
a fourth gate electrode disposed to be spaced apart from the second gate electrode in the second horizontal direction,
wherein the fourth gate electrode is disposed between the first gate electrode and the third gate electrode.

11. The sub wordline driver according to claim 10, wherein a side surface of the second gate electrode and a side surface of the fourth gate electrode facing the side surface of the second gate electrode are parallel to each other.

12. The sub wordline driver according to claim 10, wherein the second gate electrode and the fourth gate electrode have the same shape.

13. The sub wordline driver according to claim 1, wherein at least a portion of the second channel region overlaps with each of the first channel region and the third channel region in the first horizontal direction.

14. The sub wordline driver according to claim 1, further comprising:
a device isolation film disposed in the substrate and defining the active pattern,
wherein the second channel region comprises a first sidewall facing the device isolation film, and a second sidewall spaced apart from the first sidewall in the second horizontal direction, and
wherein an angle between the first sidewall and the first horizontal direction and an angle between the second sidewall and the first horizontal direction are acute angles.

15. The sub wordline driver according to claim 1, wherein each of the first gate electrode and the second gate electrode comprises a polysilicon layer, a metal barrier layer, and a metal layer, which are sequentially stacked on the substrate.

16. A sub wordline driver, comprising:
a substrate comprising an active pattern; and
a first gate electrode, a second gate electrode, and a third gate electrode, which are arranged on the active pattern and spaced apart from each other in a first horizontal direction,
wherein the active pattern comprises a first portion overlapping with the first gate electrode in a vertical direction, a second portion overlapping with the second gate electrode in the vertical direction, and a third portion overlapping with the third gate electrode in the vertical direction, and
wherein the active pattern comprises a first recess and a second recess, which are disposed between the first portion and the third portion and spaced apart from each other with the second portion interposed therebetween.

17. The sub wordline driver according to claim 16, wherein a width of the first recess in the first horizontal direction is different from a width of the second recess in the first horizontal direction.

18. The sub wordline driver according to claim 16,
wherein the active pattern further comprises a third recess disposed between the first recess and the second recess,
wherein the first recess overlaps with the second recess in the first horizontal direction, and
wherein the third recess overlaps with the second portion in a second horizontal direction perpendicular to the first horizontal direction.

19. The sub wordline driver according to claim 16,
wherein the second portion extends in a third horizontal direction that forms an acute angle with respect to the first horizontal direction, and
wherein a width of the second portion in a second horizontal direction perpendicular to the first horizontal direction is constant.

20. A semiconductor memory device, comprising:
a memory cell comprising a bit line, a wordline intersecting with the bit line, and an information storage structure; and
a sub wordline driver configured to control the wordline,
wherein the sub wordline driver comprises:
a substrate comprising an active pattern, wherein the active pattern comprises a first channel region, a second channel region, and a third channel region, which are disposed to be spaced apart from each other in a first horizontal direction;
a device isolation film disposed in the substrate and defining the active pattern;
a first gate electrode disposed on the first channel region and extending in a second horizontal direction perpendicular to the first horizontal direction;
a second gate electrode disposed on the second channel region; and
a third gate electrode disposed on the third channel region and extending in the second horizontal direction,
wherein the second channel region extends in a third horizontal direction that forms an acute angle with the first horizontal direction, and a width of the second channel region in the third horizontal direction is greater than a width of the second channel region in the first horizontal direction, and
wherein the active pattern comprises a pair of recesses disposed in an alternating fashion between the first channel region and the third channel region, and spaced apart from each other with the second channel region interposed therebetween.
